(19) United States
(12) Patent Application Publication
(10) Pub. No.: US 2012/0003779 A1
(43) Pub. Date: Jan. 5, 2012

(54) ABRASION-ETCH TEXTURING OF GLASS

(75) Inventor: Trevor Lindsay Young, Botany (AU)

(73) Assignee: CSG Solar AG

(21) Appl. No.: 12/675,389

(22) PCT Filed: Aug. 29, 2008
(86) PCT No.: PCT/AU2008/001281

§ 371 Date: Feb. 3, 2011

(30) Foreign Application Priority Data
Aug. 31, 2007 (AU) 2007904724

(51) Int. Cl. H01L 31/18; C03C 15/00; C23F 1/00

(52) U.S. Cl. 438/71; 216/83; 216/97; 216/53; 257/E31.13

(57) ABSTRACT

A method for texturing a surface of a substrate comprising creating micro-fractures in the surface of the substrate to be textured, and etching the surface of the substrate to be textured to open the micro-fractures.

### INTRODUCTION

The present invention provides a method of texturing substrates for applications such as thin film silicon solar cells and modules where the cells are formed on a foreign substrate.

### BACKGROUND

In the early development of thin film crystalline silicon solar cells on foreign substrates such as glass, it was postulated that texturing of the glass substrates (such as borosilicate and sodalime glass) would enhance light trapping and thereby increase device current. While a variety of direct texturing methods have been suggested and trialled none has resulted in the anticipated improvements and some have resulted in loss of device characteristics. When a “sol-gel texturing” (bead-coating) process was discovered in 1998 and found to reduce shunting problems, interest was lost in direct texturing of the glass in favour of applying the sol-gel texturing layer. However the bead coating process produces surface features separated by flat surface areas whereas a more random and complete surface texturing may give better results.

### SUMMARY

According to a first aspect a method is provided for texturing a surface of a substrate comprising:

i) creating micro-fractures in the surface of the substrate to be textured;

ii) etching the surface of the substrate to be textured.

The etching step preferably opens the micro-fractures and removes weakly attached material.

The substrate prepared in this way is particularly useful for the fabrication of silicon-on-glass thin film solar cells, and to that end barrier layers and silicon may be deposited onto a textured glass sheet subsequently to the texturing steps and formed into PV modules.

Preferably, the substrate used for a thin film crystalline silicon on glass (CSG) photovoltaic module is a glass sheet such as a borosilicate glass (BSG) sheet.

The method of creating micro-fractures in the surface of the substrate preferably comprises impacting or abrading the surface of the substrate to be textured with grit. This may involve dry sand blasting, lapping with a slurry, sand paper abrasion or wet sand blasting.

The etching may be performed as an acid etch of the micro-fractured surface with a solution of hydrofluoric acid (HF) to remove loose or fractured glass inclusions. The etch is preferably performed until the micro-fractures are opened and form “U” shaped valleys while the inclusions are substantially removed.

Several methods can be used to abrade the glass substrate, for example:

i) sand-paper abrasion (where the generic term “sand paper” is used to indicate any paper or fabric-backed abrasive sheet regardless of the type of backing or abrasive grit which it carries);

ii) hand lapping with an abrasive slurry on a metal lapping plate;

iii) lapping with a rotating disc;

iv) lapping with an orbital sander;

v) dry blasting with an abrasive grit; or

vi) wet blasting with an abrasive grit.

The preferred abrasion method involves impacting one side of the as-supplied glass using a dry sand blaster and abrasive grit. (The generic term “sand-blasting” is used here even though the abrasive used may not be sand.)

The abrasive grit is preferably silicon carbide powder although other materials may be used such as aluminium oxide (alumina), corundum, cubic boron nitride (CBN), boron carbide, zirconia/alumina alloys, crushed glass, glass beads, olivine sand, perlite graded sand, cut metal wire, steel shot or steel grit.

Abrasive grits having a mesh number of 300 to 1200 may be used and preferably an 800 mesh silicon carbide powder will be used.

The acid etch is preferably performed with an aqueous HF acid solution in the range of 1 to 20% [w/w] and preferably a solution of 5% [w/w] HF acid. The HF may be buffered with a suitable buffer solution such as an aqueous solution of NH₄F. Buffered HF may be prepared by mixing 50% [w/w] HF with 40% [w/w] NH₄F in the ratio 1:6-1:7 HF: NH₄F [v/v]. The etch time is preferably optimised to remove fractured glass inclusions whilst retaining a sufficiently fine texture for good light trapping and will vary depending on other factors such as the type of glass, acid concentration, temperature and the size of grit used in the micro-fracturing step. For borosilicate glass abraded with a grit size of 800 mesh, a 12 minute etch with 5% [w/w] HF at 24 degrees C. is found to be effective.

A cleaning step preferably follows the micro-fracturing step to avoid excessive contamination of the HF etch bath. The cleaning step may comprise rinsing in water and wiping to remove loose glass and abrasive dust. The cleaning step may preferably be performed using a glass washer.

### BRIEF DESCRIPTION OF THE FIGURES

Embodiments of the texturing method will now be described, by way of example with reference to the accompanying drawings and images in which:

FIG. 1 schematically illustrates a substrate in the process of lapping with an orbital sander;

FIG. 2 shows a bottom view of a lapping plate;

FIG. 3 schematically illustrates a substrate being lapped in a purpose designed lapping apparatus;

FIG. 4 schematically illustrates a substrate being sandblasted using a hand-held sandblasting gun;

FIG. 5 schematically illustrates a substrate being sandblasted in an automated sandblasting apparatus;

FIG. 6 shows several substrates being etched in an acid bath;

FIG. 7 schematically shows an alternative spray on etching arrangement;

FIG. 8 (a) to (o) are scanning electron microscope (SEM) images of sand blasted substrates after acid etching in 5% [w/w] HF for 0, 1, 2, 4, 7, 10, 12 and 15 minutes respectively at magnifications of 10,000×(a) to (h) and 3,000×(i) to (p);

FIGS. 9 (a) and (b) are optical microscope images of a sand blasted substrate (a) before and (b) after acid etching in 5% [w/w] HF for 10 minutes respectively;

FIG. 10 graphically illustrates results of different etch times on Efficiency (Eff), Voltage (V_{0.1}) and Current (J_{sc});

FIG. 11 graphically illustrates minimodule efficiency versus grit size (higher number means finer grit);

FIG. 12 schematically illustrates reduced atomic H and minority carrier diffusion lengths required with a steep texture; and

FIG. 13 illustrates improved coupling of light into silicon for micro-fracture and etch textured substrates.

### DETAILED DESCRIPTION OF TEXTURING METHODS

A simple method will be described for texturing borosilicate glass (BSG) substrates for thin film crystalline silicon on glass (CSG) photovoltaic modules. The method involves forming micro-fractures on a surface of the glass substrate by impacting or abrading one side of the as-supplied glass (for example, using a sand blaster with 800 mesh silicon carbide powder or lapping with a slurry of 800 mesh silicon carbide powder in water), followed by a cleaning step and an acid etch (preferably in 5% [w/w] HF acid). (The generic term “sand-blasting” is used here even though the abrasive used is not sand). The acid etch time is optimised to open the microcracks and remove fractured glass inclusions whilst retaining a sufficiently fine texture for good light trapping (optimised at 12 minutes when performed after abrasion with an 800 mesh abrasive). Subsequently, barrier layers and silicon are deposited onto the textured glass and formed into PV modules. Abrasion-etch textured glass substrates have resulted in record short-circuit current density (J_{sc}) and energy conversion efficiency (Eff) for CSG modules, and compared to bead-coat texturing, can give a more aesthetically pleasing finished product because of the significantly lower number of short cracks in the silicon and the improved general appearance. A variety of techniques might be used to form micro-fractures in the surface of a glass sheet destined for use as a substrate in a thin film silicon-on-glass solar cell. These include several impacting and abrading processes which are found to fracture the glass surface substantially uniformly to produce an even distribution of micro-fractures.

In addition to lapping with an orbital sander and dry sand-blasting, other methods of abrasion have been tested including the use of sandpaper abrasion, hand lapping with silicon carbide slurry on a cast iron lapping plate, lapping with a rotating disc and wet sand-blasting. Most of these various methods produce acceptable results but are less efficient, more costly or less easily adapted to a production situation.

Sandpaper abrasion is slow (30 minutes per 15×15 cm sample), uses a lot of sandpaper (actually waterproof SiC paper) and tends to make deep scratches that subsequently cause visually unacceptable cracks in the silicon film.

Hand lapping with silicon carbide slurry on a lapping plate is faster (5 minutes per 15×15 cm sample). It is more uniform than sandpaper but still makes undesirable scratches and cracks in the silicon film.

Lapping with an orbital sander is uniform and results in a surface reasonably free of scratches. The time to process a sample (about 60 minutes for a 39×30 cm sheet) depends greatly on how flat the glass sheet is to begin with.

Lapping with a small rotating disc avoids problems associated with starting with slightly warped glass because the small disc can follow the shallow, long-range contours of the sheet. This process can make scratches and may be difficult to scale up.

Dry sand-blasting cannot make scratches, is not affected by warped substrates and is easily scaled up for use with commercial size modules.

Wet sand-blasting systems are slow and expensive and to date the results have not been as good as for dry sand-blasting.

The two most preferred abrasion processes are described in detail below.

### Orbital Lapping

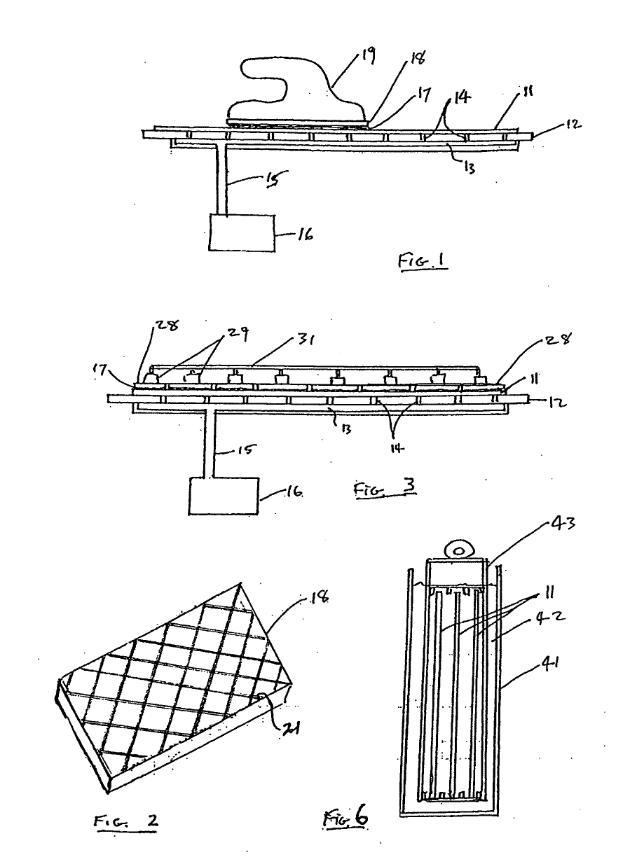

With orbital lapping, a sheet of the glass to be textured (e.g. Schott Borofloat) is positioned horizontally on a flat supporting surface with the side to be textured facing up. In the method employed for prototype testing, as shown in FIG. 1, the sheet 11 is held in position using a vacuum chuck 12, or adhesive tape applied to the corners of the sample. Alternatively, a film of water located between the glass and supporting surface can be used to hold the glass in position. Approximately 20 ml of silicon carbide slurry 17 (800-grit in water in a ratio of 100 g per litre) is applied to the glass surface to be textured. Vacuum for the chuck 12 is provided by a vacuum pump 16 connected by a vacuum hose 15 to a vacuum chamber 13 of the chuck. Holes 14 in the chuck surface communicate the vacuum to the underside of the substrate 11 holding it to the chuck 12.

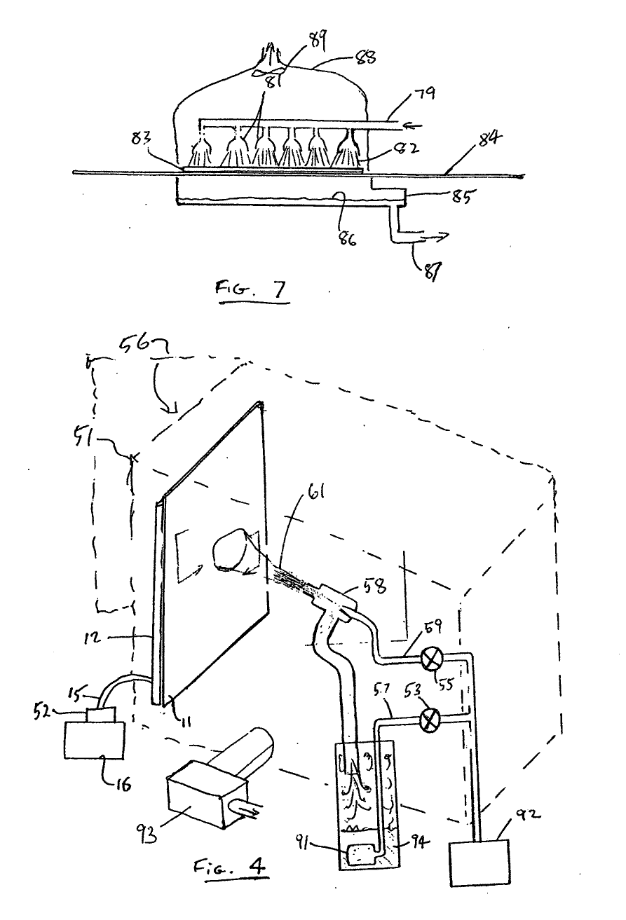

An orbital sander 19 fitted with a grooved aluminium lapping plate 18 is placed on the surface to be textured so that a film of slurry spreads between the sander's lapping plate 18 and the substrate 11. Referring to FIG. 2, a bottom view of the lapping plate 18 is provided showing the grooves 21, which are in the order of 1 mm wide and spaced with a pitch of approximately 25 mm in a square cross hatched pattern to allow air to enter under the plate for ease of movement of the lapping plate across the glass surface.

When the sander is energised to begin abrading the glass surface, the operator guides the sander slowly across every part of the surface to be textured. Little or no additional downward force is required on the sander which may achieve sufficient downward force from its own weight. The operator may have to periodically apply fresh slurry and continue abrading the surface until the surface is uniformly matt. This takes about 60 minutes for a 39×30 cm glass sheet. The process time depends greatly on the initial flatness of the sample. After the sample is fully abraded (has a completely matt surface) it is thoroughly cleaned to remove the abrasive grit. A rinse and wipe with a cloth is sufficient. The glass can also be washed in a glass washer if desired.

In a production environment a larger abrading apparatus might prove beneficial by allowing an entire surface of a sheet of glass to be abraded simultaneously as seen in FIG. 3. The lapping plate 28 may be connected to a remote drive (not shown) by a mechanical linkage 31 via flexible bushes 29. (Connection is also possibly via a hydraulic linkage to minimise safety issues.) The lapping plate 28 might be dimensioned to cover the sheet to be textured. This might require an articulated lapping plate or a plurality of discrete lapping plates to accommodate surfaces that are not completely flat. Alternatively abrasion might be performed in a band across a sheet as it is passed under or over an abrading station. In such arrangements slurry material might be supplied under pressure to the surface through ports in the lapping plate to replace slurry material escaping from the edges. Escaping slurry material could be , captured and recycled.

### Sand Blasting

The sand blasting method employed to form micro-fractures in the surface of the glass substrate requires a sand blaster suitable for use with fine abrasive grit. Within the sand blaster, compressed air flows via a porous stone into a reservoir of abrasive grit, levitating the particles and carrying them to a conventional sand-blasting gun. A high pressure blast of compressed air ejects the particles from the gun at high speed.

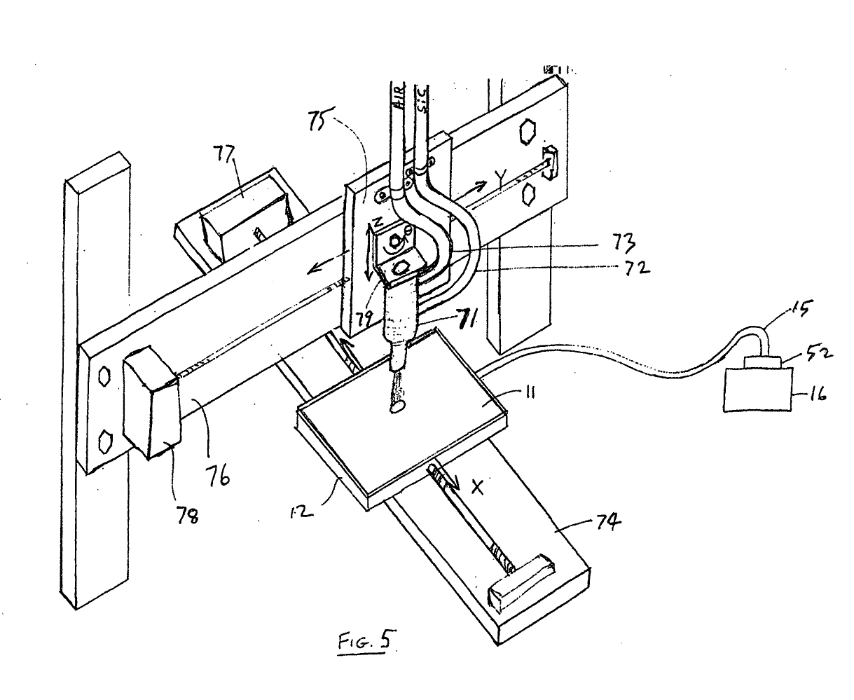

Referring to FIG. 4, the preferred method comprises the following steps:
Place a vacuum chuck 12 capable of holding the work piece inside the sand blaster cabinet 51 at a convenient position and angle for blasting. The chuck is positioned such that one face of the glass 11 will be exposed to the sand blasting and the other surface will be shielded. The vacuum pump 16 is protected from abrasive grit by a filter 52;
Place the glass sample on the vacuum chuck and energise the vacuum pump motor to hold the sample in this position;
Close the sand blaster cabinet door 56;
Switch on the sand blaster to operate the dust extraction system 93 and the air compressor 92;
Open the compressed air valve 53 and adjust the pressure on the purge line 57 to give sufficient flow of compressed air through the porous stone 91 and bed of abrasive grit 94 to levitate a cloud of abrasive grit and carry it to the gun 58;
Depress the foot switch 55 to open the compressed air blast line 59 and adjust the blast pressure;
Once the purge pressure and blast pressure are set, sand-blasting of the sample can begin;
Scan the blast 61 from the gun 58 backwards and forwards across the substrate 11, overlapping the scans slightly. In the prototype system the gun 58 is hand held. Important parameters are the distance between the gun 58 and the substrate 11, the scan speed across the sample, the overlap between scans and the angle of incidence of the blast from the gun. These will depend upon the equipment used;
The blasting is continued until the specular reflection of the original surface has disappeared. This may take a few minutes for a 15×15 cm sample. The process time depends greatly on the blasting parameters being used. It does not matter much if some parts of the sample are processed more than other parts but every part should be processed at least once.

After the sample is fully covered in micro-fractures (has a completely matt surface) it is thoroughly cleaned to remove the abrasive grit. A rinse and wipe with a cloth is sufficient. Alternatively, the glass can also be washed in a glass washer.

Again some scaling and automation of features will be required to make this abrasion method suitable for a production environment. One possible automated solution is illustrated in FIG. 5 in which the vacuum chuck 12 carrying the glass sheet 11 in a horizontal orientation is in turn carried on a slide of a one dimensional translation device 74 which moves the glass backwards and forwards under the sand blasting gun 71 in the ‘X’ direction. The gun 71 is mounted on a carriage 75 which travels on a slide of another one dimensional translation device 76 which moves the sand blasting gun 71 backwards and forwards over the glass in the ‘Y’ direction. Silicon carbide and air are delivered to the gun 71 via hoses 72, 73. The motion of the sliding components will be driven by programmable X and Y axis motors 77, 78. These motors will be mounted outside the sand blasting cabinet (not shown) to protect them from being damaged by the abrasive grit. The bracket 79 that attaches the gun 71 to the Y axis slide will enable adjustment of the distance between the gun and substrate in a third orthogonal direction ‘Z’. The bracket will also enable the angle θ at which grit impacts the substrate to be adjusted. This apparatus provides control of the scan rate, overlap, working distance and angle of impact of grit with the glass sheet.

### Hydrofluoric Acid Etching

The sample should be clean, dry and at room temperature before it is etched.

Referring to FIG. 6, for the acid etch step, the substrate 11 is immersed in a 5% [w/w] HF bath 42 contained in a tank 41 (the HF bath should be located in a fume cupboard) for the required etch time. The etch time is optimised for the type of glass, abrasion process conditions and etch temperature. Usually, Schott Borofloat glass abraded with 800 grit SiC is etched for 15 minutes at 19° C., 12 minutes at 24° C. or 10 minutes at 26° C. A plurality of substrates 11 may be suspended on a rack 43 and etched simultaneously. The substrates may be agitated or the etchant stirred to achieve faster etching at the same temperature. There is no need to protect the un-abraded surface from the acid etchant.

Buffered HF (comprising a buffering agent such as ammonium fluoride NH₄F and HF may also be used rather than unbuffered HF solution.

An alternative etching arrangement is illustrated in FIG. 7 which shows a glass sheet 83 translated into a processing area on a carrier belt 84 or rollers (not illustrated). A supply manifold 79 supplies 5% [w/w] HF in water to spray heads 81 which spray the HF 82 onto the glass sheet 83 with excess HF 86 collected in a sump 85 and recycled via a drain 87. A suitable buffered solution would be 6.5% HF and 35% NH₄F in water [w/w]. A fan 81 in fume hood 88 draws off fumes escaping from the processing area. After etching, the glass sheet is transported to an adjacent area for drying. The substrate may be dried for example by blowing with dry nitrogen or baking in air. Air drying can be performed at temperatures in the range of 150-500° C. and will preferably be performed for 15 minutes (±1 minute) at 430° C. (±20° C.).

After drying thoroughly, the substrate is ready for subsequent processing, including depositing barrier layers and silicon which typically comprise a silicon dioxide layer, a silicon nitride layer and 2.0-2.4 microns of silicon. The silicon layer will typically be an amorphous layer which is later crystallised to form a polycrystalline layer.

### Process Optimisation and Results

Thin film crystalline silicon solar cells formed on foreign substrates such as borosilicate or sodalime glass can obtain a significant improvement in solar cell performance as a result of the enhanced light trapping that is achieved when the substrate is textured. Existing methods employing a bead coating process have certain shortcomings both in terms of achieved results and the processes involved. The micro-fracture and etch process described in this specification demonstrates an improvement in resulting measured device characteristics. It also eliminates a deposited layer (beads+sol-gel) from the final device structure and several steps from the manufacturing process.

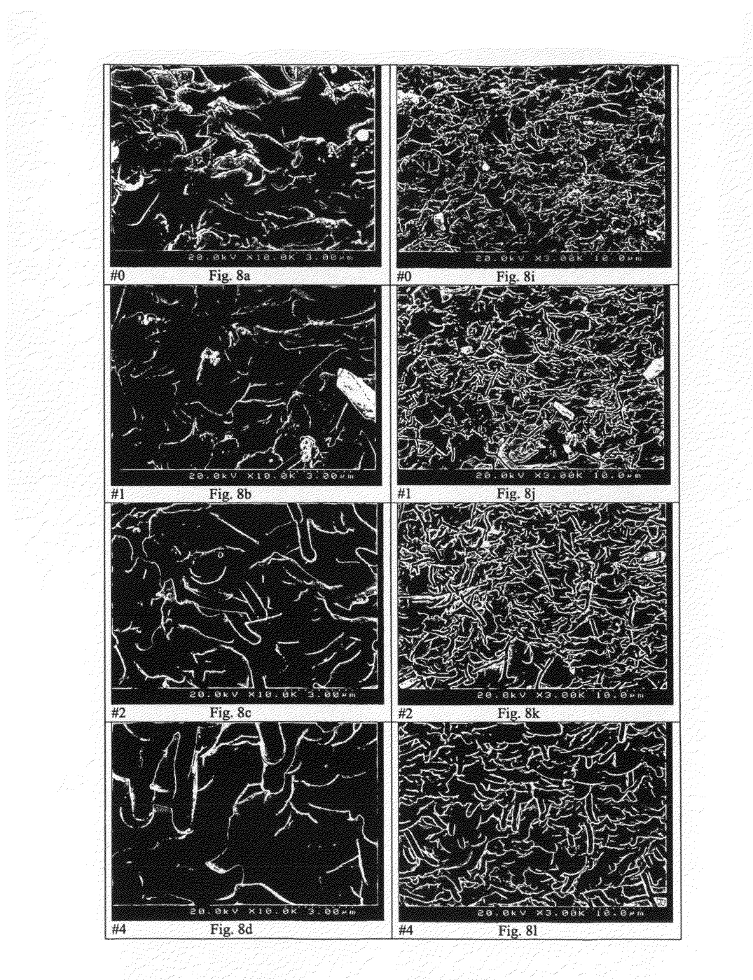

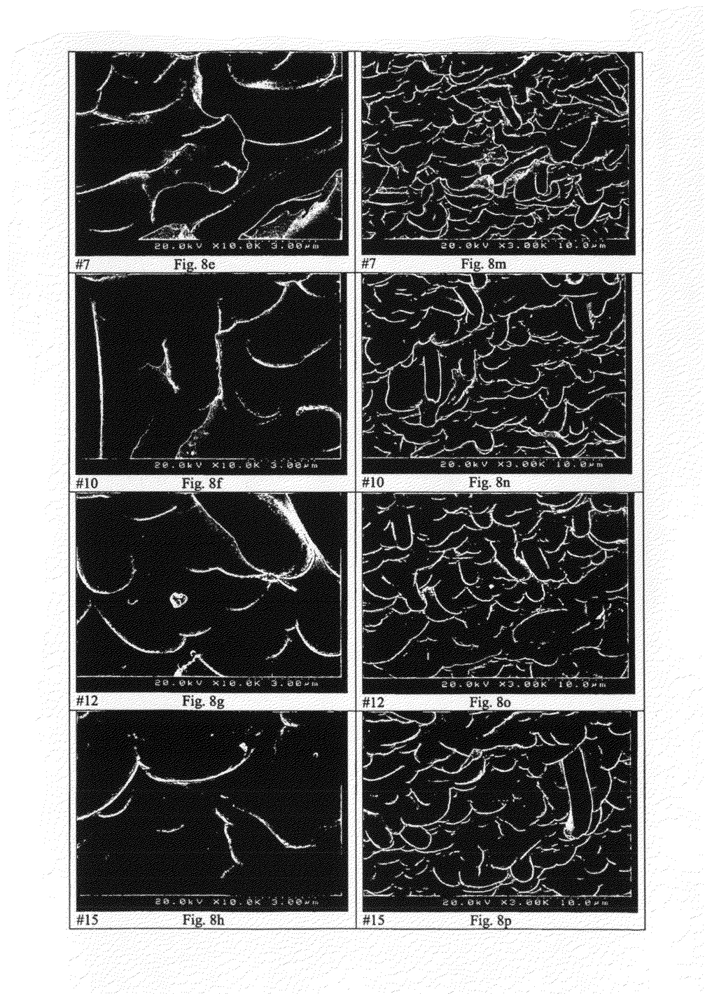

When a process of forming surface micro-fracturing (such as by surface abrasion) is followed by an acid etch, the observed effect that a simple HF etch has on a micro-fractured glass surface is quite surprising. The etch does not simply smooth the rough glass surface but instead leaves a finely-textured surface with feature sizes of a few microns, which is in the range of feature sizes useful for light trapping applications. Light scattering from the roughened surface, which is the function the textured surface is required to perform to achieve light trapping, actually increases during the initial stages of the etch. But without further etching cell output is degraded due to other effects resulting from the rough nature of the texturing. Observing FIGS. 8 (a) to (p), which show SEM images of substrate surfaces after 0, 1, 2, 4, 7, 10, 12, 15 minutes of etching in 5% [w/w] HF at 10,000× magnification (FIG. 8 (a) to (h) respectively) and SEM images of the same samples at 3,000× magnification (FIG. 8 (i) to (p) respectively), it is seen that the damaged surface produced by the impacting or abrading step has micro-fractures and inclusions and that these strained regions are etched faster than less damaged material. It is observed that with longer etch times the micro-fractures are opened and form “U” shaped valleys while the inclusions are substantially removed.

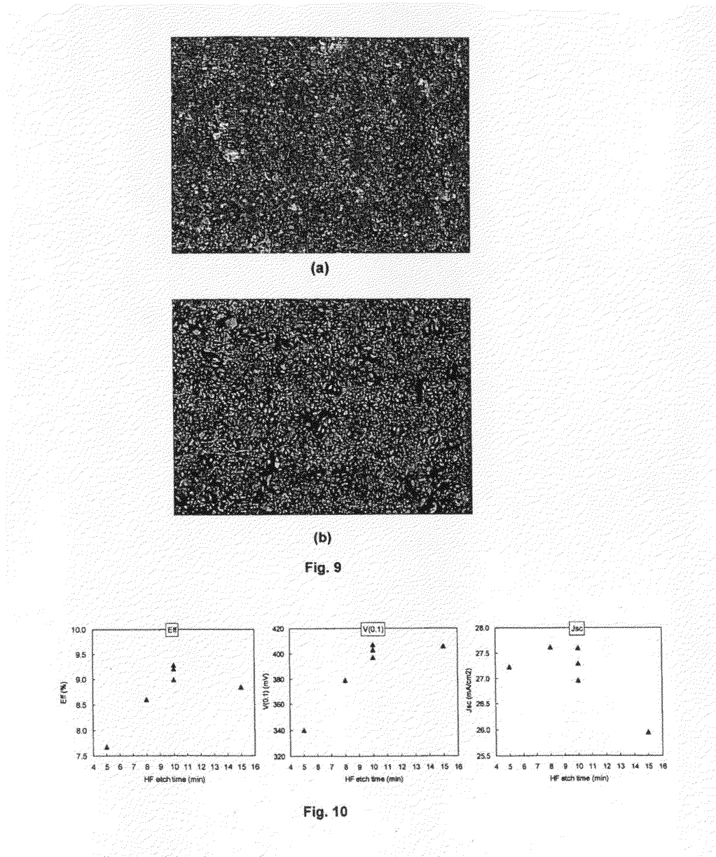

The images of FIG. 9 are reflection images. The unetched abraded surface seen in FIG. 9(a) has numerous fractured glass inclusions which appear as white areas. These are very reflective (from either side) and are therefore detrimental to device current. Devices made on such surfaces also exhibit very low voltage. As seen in FIG. 9(b), after etching for 10 minutes, the reflective inclusions are gone and the surface is covered by small rounded features that are 1-5 microns in size. The feature size can be controlled to some extent using abrasive grits of different size and different process conditions, such as blast pressure.

For optimal device performance, the texturing process requires both micro-fracture formation on the glass surface (such as by abrading) and chemical etching. Etching the glass (simply with HF acid) without first creating surface micro-fractures, produces no texture. Creating a micro-fractured surface on the glass but not etching it prior to Si deposition produces devices with very low voltage. After optimising the etch time, devices fabricated on the micro-fractured and etch textured glass have good current and voltage with the result that micro-fracture and etch textured modules routinely achieve efficiencies equaling or exceeding the best results achieved by bead-coated modules having similarly fabricated solar cell structures. Micro-fracture and etch textured modules have also routinely achieved higher short circuit current density (J_{sc}) than those achieved by bead-coated modules.

### Effect of HF Etch Time

Referring to FIG. 10 the parameter having the greatest effect on efficiency is the etch time in HF acid. Both the current and voltage of the subsequently formed device are affected substantially by etch time of the substrate. The voltage of the final device increases markedly with increasing substrate etch time for etch times of up to 10 minutes during which the fractured glass inclusions are etched out. After 10 minutes of etching, further substrate etching has little effect on device voltage.

The current of the final device increases with etch time for etch times of up to a few minutes during which the reflective interfaces of the fractured glass are removed. The device current reaches a maximum for glass substrates with a micro-fractured surface which is subsequently etched for about 8 minutes and then decreases for substrates etched for longer than this, as a result of the textured surface becoming progressively smoother from excessive etching. For most borosilicate glass samples that have a micro-fractured surface, the maximum efficiency is obtained by etching the micro-fractures for about 12 minutes in 5% [w/w] HF acid. Glass surfaces impacted or abraded with a grit coarser than 800 mesh require a few minutes more to reach optimum efficiency but their performance still does not match the performance of substrates abraded with 800 mesh abrasive and acid etched for 12 minutes. Note that these optimisations are for devices formed with a particular range of layer thicknesses and may vary for other device thicknesses.

### Effect of Grit Size

Using the dry sand blaster, it is relatively easy to change between different sizes and types of abrasive grit and to process glass samples under different operating conditions. Coarse grits (i.e. those with a lower mesh number) require a lower blast pressure to control the greater damage they do and they require a longer etch time to repair the glass surface which is more severely damaged by their impact. Experiments indicate that the grit size required to achieve an optimum combination of current, voltage, fill factor and efficiency is about 800 mesh (refer to FIG. 11). The optimum grit size for manufacturing applications also demands consideration of the compressed air consumption and the efficiency with which the abrasive can be recycled, both of which favour coarser grit.

### Efficiency

The best micro-fracture and etch textured modules consistently outperform the best bead-textured modules, due mostly to higher current. Micro-fracture and etch textured module performance is also more reliable.

### Voltage

Micro-fracture and etch textured modules maintain higher open circuit voltage at 0.1 suns V(0.1) than bead textured modules, even when the Si film is 2.2-2.4 microns thick. In the past, bead textured modules have achieved their highest values of V(0.1) for thicknesses up to 2.0 microns but with increasing silicon thickness beyond 2.0 microns voltages fall off, even when bead coating was performed with a freshly mixed bead-coating solution. Surprisingly this is not the case with abrasion and etch textured substrates.

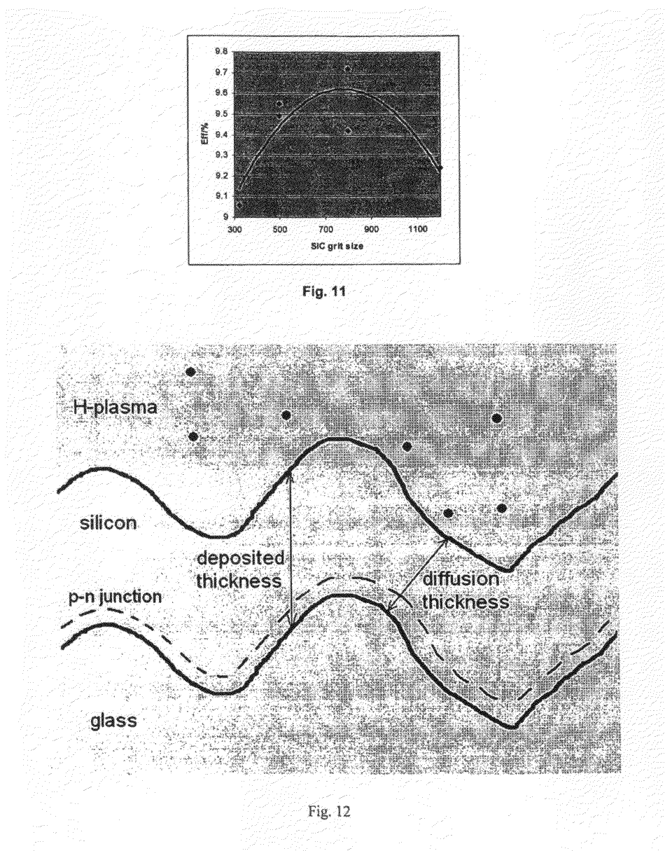

Referring to FIG. 12, the ‘deposited’ thickness of a silicon film is independent of texture but the ‘diffusion’ thickness normal to the local glass|silicon interface is reduced when the same quantity of silicon is deposited on the larger surface area of a deeply textured glass substrate. It is this diffusion thickness that affects the penetration of atomic hydrogen to, and the collection of minority carriers by, the p-n junction. The efficacy of hydrogen passivation markedly affects device voltage.

### Current

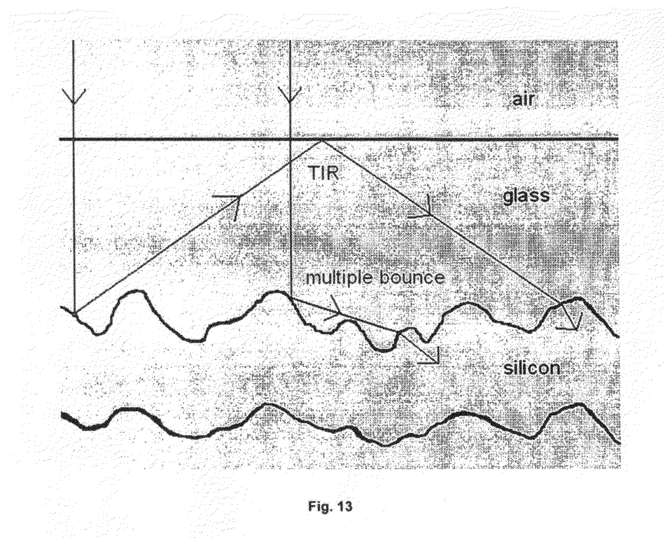

The highest J_{sc} value recorded for micro-fracture and etch textured modules exceeds the best J_{sc} values recorded for bead-textured modules, even those set by modules that have glass antireflective treatments specifically intended to boost their current. Micro-fracture and etch textured modules perform best with thick silicon because they are better able to maintain high voltage under these circumstances. The thicker silicon film should boost long wavelength ‘Red’ current but it has been found that much of the increased current comes from short wavelength ‘Blue’ light. Increased Blue light absorption appears to be due to better coupling of light into the Si film (refer to FIG. 13). If incident light reflects off the more or less Lambertian glass|silicon surface it may get a second chance to be coupled into the silicon, either directly or after a total internal reflection at the glass|air interface. The glass side reflectance from micro-fracture and etch textured crystalline silicon on glass (CSG) films is usually lower than that from co-deposited bead-textured CSG films. The transmittance is slightly higher for micro-fracture and etch textured CSG films, in spite of the generally thicker Si film, consistent with poorer light trapping in the micro-fracture and etch textured CSG films.

### Silicon Thickness

Light trapping in the silicon film depends on total internal reflection (TIR) at the surfaces of the silicon layer. There is a ‘critical angle’ for total internal reflection where a small change in angle of incidence greatly affects the fate of a photon. To meet the requirement for light trapping and TIR, the opposing surfaces of the silicon layer must not be parallel. Silicon films deposited by plasma enhanced chemical vapour deposition (PECVD) grow conformally on textured substrates such that the final surface of the silicon film is smoother than, and hence not parallel to, the initial substrate topography. The extent of smoothing depends on the radius of curvature of the surface texture and the thickness of the deposition. Consequently, there is a ‘critical radius of curvature’ where a small, perhaps seemingly insignificant, change in feature size can have a big effect on TIR and light trapping. Features on micro-fracture and etch textured substrates are a few microns in size whereas beads are smaller, usually 0.5 microns in diameter. Hence, micro-fracture and etch textured substrates work better with thicker Si films.

### Passivation Tool

Crystallised silicon films deposited on micro-fractured and etch textured substrates are more readily passivated with atomic hydrogen. It has been observed that when relatively thin silicon films were deposited on bead-textured and micro-fracture and etch textured substrates and subsequently passivated using a high performance laboratory passivation tool, all the samples were passivated equally well (that is, achieved similar voltage), leaving the difference in module efficiency to be determined by a small deficit in Red current for the micro-fracture and etch textured samples. On the other hand, when the same relatively thin silicon films were passivated with a weaker passivation tool, passivation of the material formed on a bead-textured substrate was not nearly as effective as passivation of the material formed on the micro-fracture and etch textured substrate. The resulting large voltage benefit for the micro-fracture and etch textured material overwhelmed the relatively small current deficit.

One reason micro-fracture and etch texturing makes a silicon film easier to passivate is the simple geometrical effect shown schematically in FIG. 12, where the reduced silicon thickness reduces the atomic H and minority carrier diffusion lengths required. The ‘deposited’ thickness of a silicon film is independent of texture but the ‘diffusion’ thickness normal to the local glass|silicon interface is reduced when the same quantity of silicon is deposited on the larger surface area of a deeply textured glass substrate. It is this diffusion thickness that affects the penetration of atomic hydrogen to, and the collection of minority carriers by, the p-n junction.

### Module Aesthetics

Micro-fracture and etch texturing produces a more attractive product because colour variations caused by non-uniform silicon nitride barrier layers are less visible. This should be helpful in situations where colour matching is important or when it is difficult to control the nitride thickness precisely.

Micro-fracture and etch textured modules have fewer short cracks than bead textured modules. The silicon film may have less stress due to the concertina-like ‘stretchability’ of a texture that has no flat topography. Micro-fracture and etch textured modules routinely have no short cracks visible from the glass side whereas bead-textured modules generally have some short cracks visible. Lap-abraded and etched modules can have some cracks (caused by scratches or chattering of the tool) but often the cracks are not obvious from the glass side, probably a consequence of the lack of specular reflection from the silicon|glass interface. Dry sand-blasting does not produce scratches because of the nature of the process and dry sand-blast abraded modules rarely have any hint of a crack. Micro-fracture and etch textured substrates have no hazy coating of beads at the glass|air surface. A bead-free glass surface looks better and is likely to be an advantage if an antireflection (AR) layer is to be applied subsequently.

### Other Glasses

Micro-fracture and etch texturing worked effectively on Corning Eagle glass but required a much shorter etch time (3 to 5 minutes) and the mechanical removal (by wiping with a damp cloth) of sparingly soluble reaction products. The techniques described herein with similar adjustments can also be adapted to other glasses including soda lime glasses.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A method for texturing a surface of a substrate comprising:
i) creating micro-fractures in the surface of the substrate to be textured;
ii) etching the surface of the substrate to be textured.

2. The method of claim 1 wherein the substrate is a glass substrate.

3. The method as claimed in claim 2 wherein the micro-fractures are created in the surface of the substrate by impacting or abrading the surface of the substrate.

4. The method as claimed in claim 3 wherein the impacting or abrading the surface of the substrate to be textured is performed with an abrasive grit.

5. The method of claim 2 wherein the micro-fractures are created in the surface of the substrate by dry blasting with an abrasive grit.

6. The method as claimed in claim 5 wherein the substrate is an as-supplied glass panel and the micro-fractures are created in one surface of the substrate by impacting the one surface of the substrate using a dry sand blaster and abrasive grit.

7-11. (canceled)

12. The method as claimed in claim 6 wherein the abrasive grit is one of silicon carbide powder, aluminium oxide (alumina), corundum, cubic boron nitride (CBN), boron carbide, zirconia/alumina alloys, crushed glass, glass beads, olivine sand, perlite graded sand, cut metal wire, steel shot or steel grit.

13. The method as claimed in claim 12 wherein the size of the grit is in the range of mesh number 300 to 1200.

14. The method as claimed in claim 13 wherein the abrasive grit is an 800 mesh silicon carbide powder.

15. The method as claimed in claim 1 wherein the etching is performed as an acid etch of the micro-fractured surface with a solution of hydrofluoric acid (HF).

16. The method as claimed in claim 15 wherein the etch is performed until the micro-fractures are opened and form “U” shaped valleys.

17. The method as claimed in claim 16 wherein the etch is performed until fractured glass inclusions are substantially removed.

18. The method as claimed in claim 17 wherein the acid etch is performed with an aqueous HF acid solution in the range of 1 to 20% [w/w].

19. The method as claimed in claim 18 wherein the acid etch comprises a 12 minute etch with a 5% [w/w] aqueous solution of HF.

20. The method as claimed in claim 19 wherein a cleaning step is performed following the micro-fracturing step.

21. The method as claimed in claim 20 wherein the cleaning step following the micro-fracturing step comprises washing in water and drying.

22. The method as claimed in claim 21 wherein the washing step comprises washing the substrate in a glass washer.

23. The method as claimed in claim 22 wherein the drying step following the acid etch step comprises baking or blowing with dry nitrogen.

24. The method as claimed in claim 1 wherein the substrate is a sheet of borosilicate glass (BSG).

25. The method as claimed in claim 1 wherein one or more barrier layers are applied to the textured surface of the substrate and a silicon film is subsequently deposited onto the textured surface of the substrate and formed into a photovoltaic device whereby the substrate and the silicon photovoltaic device form a solar cell module.

26. (canceled)
